(19) United States
(12) Patent Application Publication
(10) Pub. No.: US 2026/0256030 A1
(43) Pub. Date: Aug. 27, 2026

(54) OUTER BENDING LEADFRAME TECHNOLOGY

(71) Applicant: SEMICONDUCTOR COMPONENTS INDUSTRIES, LLC, Scottsdale, AZ (US)

(72) Inventors: Cheng HU, Suzhou (CN); Kun FENG, Shanghai (CN); LiJuan SHEN, ChongQin (CN)

(73) Assignee: SEMICONDUCTOR COMPONENTS INDUSTRIES, LLC, Scottsdale, AZ (US)

(21) Appl. No.: 19/064,785

(22) Filed: Feb. 27, 2025

(51) Int. Cl. H10W 90/00; H10W 70/00; H10W 72/00; H10W 74/10

(52) U.S. Cl. CPC H10W 90/701; H10W 70/099; H10W 72/07502; H10W 72/884; H10W 74/111; H10W 90/734; H10W 90/755

(57) ABSTRACT

Described implementations provide an apparatus that includes a direct bonded metal (DBM) substrate including at least a metal layer coupled to an insulating layer, and a leadframe of a package including an inner conductive portion and an outer conductive portion, the outer conductive portion including an outer angled portion, wherein the inner conductive portion is configured to be disposed in a molding material of the package, wherein the inner conductive portion is coupled to the metal layer of the DBM substrate.

### TECHNICAL FIELD

This description relates to semiconductor packaging techniques for power modules.

### BACKGROUND

Semiconductor devices have been developed for use in various applications associated with power supply and power management. For example, power modules may use a combination of a transistor and a diode, such as an Insulated Gate Bipolar Transistor (IGBT) and a Fast Recovery Diode (FRD). Power modules may also include integrated circuits (ICs). Semiconductor devices packaged within a power module may have high demands in terms of electrical, mechanical, and thermal reliability.

Integrated circuit packaging is the final stage of semiconductor device fabrication, in which the semiconductor die, or dies, are encapsulated in a package that prevents physical damage and corrosion. The package supports the electrical contacts which connect the semiconductor devices to a circuit board. An integrated circuit package or semiconductor device package includes a metal, plastic, glass, and/or ceramic casing containing one or more semiconductor devices or integrated circuits. Individual components are fabricated on semiconductor wafers (commonly silicon, or silicon carbide wafers) before being diced into die, tested, and packaged. The semiconductor device package provides a means for connecting the semiconductor devices or integrated circuits to the external environment, such as a printed circuit board, via leads such as lands, balls, or pins and provides a means for protection against threats such as mechanical impact, chemical contamination, and/or light exposure. An example package may include multiple semiconductor die mounted on a substrate. With an increasing demand for high-performance integrated circuits, new improvements are needed in packaging technologies to improve the performance and reliability of integrated circuits.

### SUMMARY

In some aspects, the techniques described herein relate to an apparatus, including: a direct bonded metal (DBM) substrate including at least a metal layer coupled to an insulating layer; and a leadframe of a package including an inner conductive portion and an outer conductive portion, the outer conductive portion including an outer angled portion, where the inner conductive portion is configured to be disposed in a molding material of the package, and where the inner conductive portion is coupled to the metal layer of the DBM substrate.

In some aspects, the techniques described herein relate to an apparatus including: a direct bonded metal (DBM) substrate including at least a metal layer coupled to an insulating layer; a leadframe of a package including an inner conductive portion and an outer conductive portion, where the outer conductive portion includes a first conductor provided at a first lateral position, a second conductor provided at a second lateral position that is disposed below the first lateral position, and an outer angled portion coupling the first conductor to the second conductor; where the inner conductive portion includes an inner angled portion and is coupled to the metal layer of the DBM substrate; where the inner conductive portion is configured to be disposed in a molding material of the package; where at least the second conductor and the outer angled portion of the outer conductive portion are configured to be disposed outside of the molding material of the package; and where at least the second conductor and the outer angled portion of the outer conductive portion are configured to be cut or trimmed away from the package.

In some aspects, the techniques described herein relate to a method, including: forming a leadframe of a package including an inner conductive portion and an outer conductive portion, where the outer conductive portion includes a first conductor provided at a first lateral position, a second conductor provided at a second lateral position that is disposed below the first lateral position, and an outer angled portion coupling the first conductor to the second conductor, and where the inner conductive portion includes an inner angled portion; coupling the inner conductive portion to a metal layer of a direct bonded metal (DBM) substrate; and forming a molding material of the package, where the inner conductive portion is disposed in the molding material of the package, and where at least the second conductor and the outer angled portion of the outer conductive portion are disposed outside of the molding material of the package.

The details of one or more implementations are set forth in the accompanying drawings and the description below. Other features will be apparent from the description and drawings, and from the claims.

### BRIEF DESCRIPTION OF THE DRAWINGS

FIG. 1 is a cross-sectional view of a semiconductor device package.

FIGS. 2A and 2B are cross-sectional views of semiconductor device packages in which an outer angled portion of a leadframe has different outer bending depths.

FIG. 3 is a flow chart illustrating a method of making a semiconductor device package.

### DETAILED DESCRIPTION

Semiconductor device packages (e.g., semiconductor device modules) should provide high levels of electrical, mechanical, and thermal reliability, in a cost-efficient and space-efficient manner. An aspect of electrical reliability may include meeting a creepage requirement. Creepage or a creepage distance may include or may refer to the shortest path along the surface of an insulating material (e.g., such as a printed circuit board (PCB)) between two conductors, such as, for example, between a high voltage conductor and a ground terminal. A creepage requirement or creepage distance requirement, which may be the minimum required distance between two terminals of the package, may be based on the voltage between the two terminals and the insulative properties of the path or PCB between the two terminals. Providing a semiconductor device package design that provides creepage distances between terminals that meet creepage requirements may prevent short circuits or electrical shock, and may contribute to long-term reliability of the package.

Also, during manufacture of semiconductor device packages, a wirebond machine, which may include a bond tool, may be used to perform wire bonding in which bond wires (or wire bonds) may be connected to various components of a semiconductor device package. A bond tool may touch or contact various components of the semiconductor device package during wire bonding to connect the bond wires to various components. The wirebond machine may have a limited bond tool contact range, which is the range or distance that the bond tool can contact or reach within the semiconductor device package. The bond tool contact range may be provided with respect to or based on a machine rail height (the height or lateral position of the machine rails of the wirebond machine). Thus, for example, a wirebond machine may have a bond tool contact range measured from the height of the machine rail(s) of the wirebond machine. Therefore, a bond tool contact depth (e.g., maximum bond tool contact depth), which may be the depth (e.g., lowest point or lowest depth) within a semiconductor device package that a bond tool of a wirebond machine may contact or reach, may depend on or may be based on the machine rail height and the bond tool contact range. Challenges exist in providing semiconductor device package designs that both satisfy creepage requirements for terminals of the package and accommodate deep bond tool contact depths without requiring custom bond tools for different bond tool contact depths.

Accordingly, described implementations provide a semiconductor device package that includes a direct bonded metal (DBM) substrate including at least a metal layer coupled to an insulating layer, and a leadframe of a package including an inner conductive portion and an outer conductive portion, the outer conductive portion including an outer angled portion, where the inner conductive portion is configured to be disposed in a molding material of the package, where the inner conductive portion is coupled to the metal layer of the DBM substrate.

In example embodiments, the outer angled portion may be configured to be disposed outside of the molding material of the package. Also, at least a portion of the outer conductive portion, including the outer angled portion, is configured to be trimmed or cut away from the package.

In example embodiments, the outer conductive portion may include: a first conductor provided at a first lateral position; a second conductor provided at a second lateral position that is disposed below the first lateral position, where the second lateral position of the second conductor is laterally closer to the DBM substrate than the first lateral position of the first conductor; and the outer angled portion couples the first conductor to the second conductor. For example, the outer angled portion and the second conductor may be configured to be disposed outside of the molding material of the package, and may be configured to be cut or trimmed away from the package.

By providing a leadframe with an outer conductive portion that includes the outer angled portion and/or the second conductor (that is disposed below the first conductor of the outer conductive portion), a deeper bond tool contact depth may be achieved by providing a lower machine rail height of the wirebond machine (e.g., during wire bonding for the package) without impacting or decreasing a creepage distance with respect to the first conductor of the outer conductive portion. This deeper bond tool contact depth may be achieved while maintaining the creepage distance that meets the creepage requirement for the first conductor. Also, in order for the bond tool to reach a deeper bond tool contact depth, a custom bond tool is not required. Rather, an outer bending depth of the outer angled portion may be controlled or adjusted based on a semiconductor device package design or depth of components of the semiconductor device package to be reached or contacted by the bond tool. Also, the dimensions of the semiconductor device package are not impacted by providing the outer angled portion or second conductor, since the outer angled portion and the second conductor of the outer conductive portion will be cut or trimmed away from the semiconductor device package.

According to example embodiments, a creepage distance is provided, or a creepage requirement is met, with respect to the first conductor; and where a bond tool contact depth to one or more die or other components in the package during wire bonding is provided with respect to the second conductor.

According to example embodiments, the outer conductive portion may include: a first conductor provided at a first lateral position; a second conductor provided at a second lateral position, the second conductor being parallel to the first conductor, and the second conductor at the second lateral position being laterally closer to the DBM substrate than the first conductor; and where a bond tool contact range from a machine rail of a wirebond machine to a component of the package is provided with respect to the second conductor based on contact of the machine rail of the wirebond machine with the second conductor.

According to example embodiments, the outer conductive portion may include: a first conductor provided at a first lateral position; a second conductor provided at a second lateral position, the second conductor being parallel to the first conductor; an outer angled portion coupling the first conductor to the second conductor; and where, based on an outer bending depth provided by the outer angled portion, a second distance between the second conductor and an upper surface of the DBM substrate is less than a first distance between the first conductor and the upper surface of the DBM substrate.

According to example embodiments, a maximum bond tool contact depth within the package during wire bonding is provided with respect to the second conductor of the outer conductive portion to one or more die or other components of the package; and where a creepage distance is provided, or a creepage requirement is met, with respect to the first conductor of the outer conductive portion.

According to example embodiments, based on an outer bending depth provided by the outer angled portion, a second distance between the second conductor and an upper surface of the DBM substrate is less than a first distance between the first conductor and the upper surface of the DBM substrate, where the second conductor is configured to allow a bond tool of a wirebond machine to reach a deeper bond tool contact depth for wire bonding while one or more machine rails of the wirebond machine contact or support the package at the second conductor as compared to the one or more machine rails of the wirebond machine contacting or supporting the package at the first conductor.

According to example embodiments, the second conductor of the package is configured to enable a bond tool of a wirebond machine to reach a deeper bond tool contact depth within the package when one or more machine rails of the wirebond machine contact or support the package at the second conductor instead of at the first conductor.

According to example embodiments, the outer angled portion that connects the first conductor and the second conductor is configured to provide the second conductor at the second lateral position that is closer to an upper surface of the DBM substrate than the first conductor, to provide a lower wirebond machine rail height with respect to the DBM substrate to enable a deeper bond tool contact depth within the package during wire bonding.

According to example embodiments, the second conductor of the outer conductive portion is configured to enable one or more wirebond machine rails of a wirebond machine to contact or support the package at the second conductor for a bond tool to reach a deeper bond tool contact depth within the package during wire bonding as compared to the one or more machine rails of the wirebond machine supporting or contacting the package at the first conductor.

According to example embodiments, a machine rail height of a wirebond machine is provided at the second conductor to enable a bond tool of the wirebond machine to contact or touch a deeper bond tool contact depth within the package, as compared to a machine rail height being provided at the first conductor.

According to example embodiments, the inner conductive portion comprises an inner angled portion coupling a third conductor provided at the first lateral position and a fourth conductor that is coupled to the DBM substrate. The third conductor may be coupled to and aligned with the first conductor. The third conductor may be provided at the first lateral position. And, the fourth conductor may be provided at a third lateral position that is closer to the DBM substrate than the third conductor at the first lateral position. The fourth conductor may include a die attach pad (DAP) coupled to the metal layer of the DBM substrate.

According to an example embodiment, an apparatus may include a direct bonded metal (DBM) substrate including at least a metal layer coupled to an insulating layer; a leadframe of a package including an inner conductive portion and an outer conductive portion, where the outer conductive portion includes a first conductor provided at a first lateral position, a second conductor provided at a second lateral position that is disposed below the first lateral position, and an outer angled portion coupling the first conductor to the second conductor; where the inner conductive portion includes an inner angled portion and is coupled to the metal layer of the DBM substrate; where the inner conductive portion is configured to be disposed in a molding material of the package; where at least the second conductor and the outer angled portion of the outer conductive portion are configured to be disposed outside of the molding material of the package; and where at least the second conductor and the outer angled portion of the outer conductive portion are configured to be cut or trimmed away from the package. In example embodiments, a bond tool contact range within the package during wire bonding is provided with respect to the second conductor of the outer conductive portion to one or more die or other components of the package; and where a creepage distance is provided, or a creepage requirement is met, with respect to the first conductor of the outer conductive portion. Also, in example embodiments, the second conductor of the package is configured to enable a bond tool of a wirebond machine to reach a deeper bond tool contact depth within the package when one or more machine rails of the wirebond machine contact or support the package at the second conductor instead of at the first conductor.

Although referred to, by way of example, as a leadframe throughout this detailed description, the leadframe can include any type of conductive portion of a package (e.g., conductive portion, conductive terminal, or a conductor) that can provide an external connection point from a package. Accordingly, the leadframe can be referred to as a conductive portion of the package.

Semiconductor device packages can include a direct-bonded metal (DBM) substrate, such as, for example, a direct-bonded copper (DBC) substrate. In some implementations, DBC substrates may be used in some power modules or semiconductor device packages, because of their very good thermal conductivity. In some implementations, a DBC substrate is composed of (or may include) a ceramic oxide substrate (baseplate) (which may be referred to herein as an insulating layer, a dielectric layer or ceramic material layer) with a layer of copper coupled to one or both sides by, for example, a high-temperature oxidation process.

As noted, a DBM substrate or DBC substrate may include an insulating layer or dielectric layer (e.g., a ceramic material layer) with direct-bonded metal, for example, a patterned metal layer including one or more patterned metal layer portions disposed on at least one side of the ceramic material layer. DBM is used in power device modules, and the DBM may be connected to a leadframe through soldering, sintering or welding.

A semiconductor device package may include at least one semiconductor die mounted on a leadframe structure that includes leads providing external electrical connections (external to the package) for individual devices or integrated circuits in the semiconductor die. The semiconductor die can be mounted on a paddle or flag in the leadframe structure using a solder or a conductive adhesive. Wire bonds (which may also be referred to as bond wires or bonding wires) and/or clips may be used to electrically connect various circuits, die, leadframe, devices or other components, or electrically connect an IC or circuit to a leadframe lead, or provide other electrical connection. A wire bond (or bond wire) may form a loop (e.g., a vertical loop) that extends from a contact pad on a first semiconductor die to a contact pad on a second semiconductor die or to a post in a leadframe. Further, device contact pads on the semiconductor die may be electrically connected using, for example, wire bonds (e.g., aluminum or copper wire bonds or bond wires) to respective ones of the leads. The leadframe leads (which may be referred to as leads), which extend to outside of the package body, form external terminal pins that can be used to mount the package on a printed circuit board (PCB) or terminal strip. In some implementations, the terminal pins can be installed in sockets or soldered to a PCB or terminal strip.

For various applications (such as for power applications), the semiconductor device package may include various devices, ICs and/or circuits, e.g., such as silicon devices, silicon carbide transistors, gallium nitride devices, insulated gate bipolar transistor (IGBT), fast recovery diode (FRD), negative temperature coefficient (NTC) thermistors, integrated circuits (ICs), or other devices or circuits.

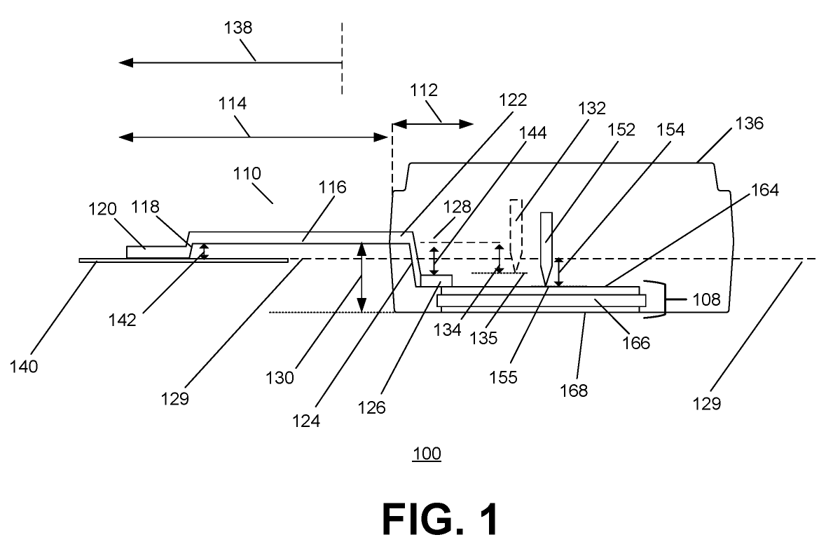

FIG. 1 is a cross-sectional view of a semiconductor device package. As shown in FIG. 1, the semiconductor device package 100 includes a DBM substrate 108 including at least patterned metal layer 164 (which may include one or more patterned metal layer portions) coupled to an insulating layer 166 (which may also be referred to as a dielectric layer or a ceramic material. DBM substrate 108 may also include a lower (or second) metal layer 168 that is coupled to a lower side of insulating layer 166. Patterned metal layer 164 and lower (or second) metal layer 168 may be copper or copper alloy, or other metal. Although not shown in FIG. 1, one or more semiconductor die may be mounted on DBM substrate 108.

Semiconductor device package 100 may include a leadframe 110, which may include an inner conductive portion 112 and an outer conductive portion 114. The inner conductive portion may be configured to be disposed in a molding material 136 of the semiconductor device package 100. The outer conductive portion 114 may be configured to be disposed outside of the molding material 136 of the semiconductor device package. The semiconductor dies, ICs, devices, DBM substrate 108 and other components of semiconductor device package 100 may be encapsulated in a molding material 136 or a mold body (such as a mold body made of a plastic or an epoxy) to protect the semiconductor dies, ICs, devices and other components of the semiconductor device package 100 against environmental threats such as mechanical impact, chemical contamination, and/or light exposure.

Outer conductive portion 114 of leadframe 110 may include a first conductor 116, a second conductor 120, and an outer angled portion 118 that couples the first conductor 116 with the second conductor 120. First conductor 116 may be provided at a first lateral (e.g., vertical) position, and second conductor 120 may be provided at a second lateral position that is disposed below the first lateral position. Thus, for example, the second conductor 120 may be laterally closer to DBM substrate 108 than first conductor 116. Outer angled portion 118 includes an outer bending depth 142, which is the lateral distance between first conductor 116 and second conductor 120, or may be the depth or distance that the outer angled portion 118 lowers (or decreases a position of) the second conductor 120 with respect to the first conductor 116. Second conductor 120 and outer angled portion 118 are horizontally further away from the fourth conductor 126, the inner conductive portion 112 and/or the molding material 136, than the first conductor 116. Second conductor 120 may be parallel with the first conductor 116.

At least a portion of the outer conductive portion 114, including at least the outer angled portion 118 and the second conductor 120, may be configured to be cut or trimmed away from the semiconductor device package 100. Section 138, for example, is or indicates a section or portion of the outer conductive portion 114 that may be cut or trimmed away from semiconductor device package 100, e.g., which may include the outer angled portion 118 and the second conductor 120. Section 138 may include a portion of the first conductor 116 (thus, a portion of the first conductor 116 may be cut or trimmed away from the semiconductor device package).

Inner conductive portion 112 of leadframe 110 may include a third conductor 122, a fourth conductor 126, and an inner angled portion 124 that couples the third conductor 122 with the fourth conductor 126. Third conductor 122 may be provided at the first lateral position and may be aligned with first conductor 116. Fourth conductor 126 may be provided at a third lateral position that is disposed below the first lateral position. Fourth conductor 126 may be parallel with the third conductor 122. Fourth conductor 126 may, for example, be a die attach pad (DAP) that may be coupled (e.g., soldered, sintered or welded) to the patterned metal layer 164 of DBM substrate 108. Inner angled portion 124 includes an inner bending depth 144, which may be a lateral distance between third conductor 122 and fourth conductor 126, or may be the depth or distance that the inner angled portion 124 lowers (or decreases a position of) the fourth conductor 126 with respect to the third conductor 122. In example embodiments, the inner bending depth 144 may be greater than outer bending depth 142.

Leadframe 110, e.g., which may include first conductor 116, outer angled portion 118, second conductor 120, third conductor 122, inner angled portion 124 and fourth conductor 126, may be formed as one integral piece, e.g., via stamping and/or etching, and then bending as necessary to provide the required shape. Leadframe 110 may be formed of copper, copper alloy or other metal. For example, a stamping tool may be used to form or provide leadframe 110.

In semiconductor device package design, ensuring safety and reliability of equipment is important. One of the factors that contributes to this goal is creepage or creepage distance. A creepage distance that meets a creepage requirement can prevent electrical breakdowns and short circuits within a package or on a printed circuit board (PCB). Creepage or creepage distance may include or may refer to the shortest path along the surface of an insulating material (e.g., such as a PCB) between two conductors, such as between a high voltage conductor and a ground terminal. The creepage requirement or creepage distance requirement, which may be the minimum required distance between two terminals of the package, may be based on the voltage between the two terminals and the insulative properties of the path or printed circuit board between the two terminals. Providing a package design that provides creepage distances that meet creepage requirements may prevent short circuits or electrical shock, and may contribute to long-term reliability of the package.

With reference to FIG. 1, creepage distance 130 is an example creepage distance, and may be the lateral distance between the first conductor 116 and the lower surface of the lower metal layer 168. For example, in order to meet the creepage requirement for first conductor 116 (e.g., which may be a high voltage terminal) and lower metal layer 168 (which may be a ground terminal), the lateral distance between first conductor 116 and lower metal layer 168 should be at least creepage distance 130.

Also, during manufacture of semiconductor device package 100, a wirebond machine, which may include a bond tool, may be used to perform wire bonding in which bond wires (also known as bonding wires, or wire bonds) may be connected between die, the leadframe 110, DBM substrate, and/or other components of semiconductor device package 100. A bond tool may touch or contact various components of the semiconductor device package 100 during wire bonding to connect the bond wires. For example, a wirebond machine may include one or more machine rails (e.g., a front machine rail and a rear machine rail of the wirebond machine) that may contact or support the semiconductor device package 100 during wire bonding. The wirebond machine may have a limited bond tool contact range, which is the range or distance that the bond tool can contact or reach within the semiconductor device package 100. The bond tool contact range (e.g., 1.1 mm) may be provided with respect to or based on a machine rail height (the height or lateral position of the machine rails of the wirebond machine). Thus, for example, a wirebond machine may have a bond tool contact range (e.g, of 1.1 mm or other range) measured from the height of the machine rail(s) of the wirebond machine. Therefore, a bond tool contact depth (e.g., maximum bond tool contact depth), which may be the depth (e.g., a lowest point or lowest depth) within the semiconductor device package 100 that a bond tool of a wirebond machine may contact or reach, may depend on the machine rail height and the bond tool contact range.

As shown in FIG. 1, in the absence of outer angled portion 118 and second conductor 120, during wire bonding, a machine rail of the wirebond machine may support or make contact with a lowest surface of outer conductive portion 114, which may be a lower surface of first conductor 116, and the machine rail would be provided at a machine rail height 128. Based on the machine rail (of the wirebond machine) provided at machine rail height 128 (which is due to the machine rail contacting the lower surface of the first conductor 116), bond tool 132 may include a bond tool contact range 134 (e.g., 1.1 mm), which may refer to the range or distance the bond tool 132 may reach or contact within the semiconductor device package 100 from the machine rail height 128. Bond tool 132 may reach a bond tool contact depth 135 (e.g., which may be the bond tool contact range 134 below machine rail height 128). As noted above, the bond tool contact depth 135 that can be reached by bond tool 132 may be based on the machine rail height 128 and the bond tool contact range 134 of bond tool 132. However, depending on the semiconductor device package design (e.g., such as a depth of DBM substrate 108 and/or location or depth of various die or other components), and based on the machine rail height 128 and the bond tool contact range 134, the bond tool 132 may be unable to reach some components within the semiconductor device package 100. Also note, for example, it is not possible in this example to lower (or decrease) the lateral position of the first conductor 116 to a lower position that is closer to DBM substrate 108 (e.g., in order to allow bond tool 132 to reach a deeper bond tool contact depth), as this would cause creepage distance 130 to decrease and violate the creepage requirement for these two terminals (creepage requirement for first conductor 116 and lower metal layer 168).

However, in example embodiments, based on providing second conductor 120 that is disposed below first conductor 116, a deeper bond tool contact depth 155 (which is deeper within the semiconductor device package 100 than bond tool contact depth 135) may be achieved by lowering the machine rail height from machine rail height 128 to machine rail height 129, without decreasing the creepage distance 130 with respect to the first conductor 116. This deeper bond tool contact depth 155 may be achieved while maintaining the creepage distance 130 that meets the creepage requirement for the first conductor 116 and lower metal layer 168, since the lateral position of first conductor 116 is not moved or lowered (the creepage distance 130 is maintained). Also, a custom bond tool is not required. Rather, the outer bending depth 142 of outer angled portion 118 may be adjusted or controlled (e.g., during forming and/or stamping of leadframe 110) based on a design of the semiconductor device package 100 including a depth of various die or components, to allow a standard bond tool (e.g., having a bond tool contact range 134 that may be fixed or limited) to be used for wire bonding for various designs of semiconductor device packages, while still meeting creepage requirements.

As shown in FIG. 1, based on the presence of second conductor 120 that is disposed below the first conductor 116, a machine rail 140 of the wirebond machine may make contact with or support a lower surface of second conductor 120, which causes the machine rail 140 to be provided at machine rail height 129. Machine rail height 129 (which may be based on the machine rail 140 contacting the second conductor 120) is lower than machine rail height 128 (which is based on machine rail 140 contacting the first conductor 116, in the absence of second conductor 120 and outer angled portion 118). The use of the second conductor 120 to provide a machine rail height 129, results in bond tool 152, with a bond tool contact range 154 (e.g, 1.1 mm), reaching a deeper bond tool contact depth 155. Bond tool contact depth 155 (based on use of second conductor 120 that is disposed below first conductor 116, making contact with the machine rail 140) may be deeper or further into semiconductor device package 100 than bond tool contact depth 135 (which is based on the first conductor 116 making contact with the machine rail 140, not shown in FIG. 1). Thus, by providing the outer angled portion 118 and second conductor 120 (in which second conductor 120 will make contact with machine rail 140 of a wirebond machine during wire bonding to provide a machine rail height 129), bond tool 152 may reach more components and reach a deeper bond tool contact depth 155 (which is deeper than bond tool contact depth 135). Note that the bond tool 132 and bond tool 152 may be the same bond tool, but may be provided or positioned differently based on a different machine rail height (bond tool 132 may be positioned based on machine rail height 128, and bond tool 152 may be positioned based on machine rail height 129). Also, the bond tool contact range 134 (e.g., 1.1 mm) for bond tool 132 may be the same as bond tool contact range 154 (e.g., 1.1 mm) for bond tool 152. Thus, in FIG. 1, bond tool 132 and bond tool 152 may be the same bond tool, with the same bond tool contact range 134, but are positioned differently based on different machine rail heights.

In example embodiments, during wire bonding, the machine rail 140 of the wirebond machine may contact or support the semiconductor device package 100 at a lowest surface of the outer conductive portion 114. In this example shown in FIG. 1, because the outer angled portion 118 has an outer bending depth 142, the second conductor 120 is disposed below the first conductor 116 (and second conductor 120 is closer to the DBM substrate 108 than first conductor 116), the machine rail 140 will contact the lower surface of the second conductor 120 (with second conductor 120 and outer angled portion 118 present), instead of contacting a lower surface of the first conductor 116 (machine rail 140 will contact first conductor 116 in the absence of second conductor 120 and outer angled portion 118). Thus, the presence of second conductor 120, disposed below the first conductor 116, causes the machine rail height of the wirebond machine to decrease (to a lower position or level) or become closer to the DBM substrate 108 (to decrease from machine rail height 128 to machine rail height 129), thereby enabling or allowing the bond tool 152 to reach a deeper bond tool contact depth 155 (which is deeper than bond tool contact depth 135 that is based on machine rail height 128).

While the bond tool 152 may reach a deeper bond tool contact depth 155 based on second conductor 120, the creepage distance 130 is not changed. In this example, the creepage distance 130, which is not changed due to the second conductor 120, is the lateral distance between the first conductor 116 (e.g., adjacent to or just outside of an edge of molding material 136) and lower metal layer 168. Thus, the techniques or embodiments described herein allow bond tool 152 to reach a deeper bond tool contact depth to reach or accommodate deeper downset package designs, without adjusting a creepage distance 130, and/or without violating a creepage requirement, and/or without requiring a custom bond tool. Also, the outer angled portion 118 and second conductor 120 may be cut or trimmed from the semiconductor device package 100 in a trim form process, and thus, there is no impact to package outline dimension. Also, adding outer angled portion 118 and second conductor 120 does not create or require any changes to an inside design (the portion of leadframe 110 and components that are inside of molding material 136) of the semiconductor device package 100.

As shown in FIG. 1, a creepage distance 130 is provided, or a creepage requirement is met, with respect to the first conductor 116, and a bond tool contact depth to one or more die or other components in the semiconductor device package 100 during wire bonding is provided with respect to the second conductor 120. For example, based on machine rail 140 contacting or supporting the semiconductor device package at a lower edge of the second conductor 120, thereby setting the machine rail 140 of the wirebond machine at machine rail height 129, which provides the improved or deeper bond tool contact depth 155. This is performed without decreasing the creepage distance 130 because the outer angled portion 118 and second conductor 120 is provided on the leadframe 110 (or leadframe 110 is formed to include the outer angled portion 118 and second conductor 120 that is disposed below the first conductor 116), without adjusting or moving the position or height of the first conductor 116 (thus, the creepage distance 130 is maintained). In this manner, an improved or increased bond tool contact depth 155 may be provided based on the outer angled portion 118 and second conductor 120, and the creepage distance 130 is provided or maintained with respect to the first conductor 116 (e.g., creepage distance 130 is maintained between first conductor 116 and lower metal layer 168 of DBM substrate 108, and meets the creepage requirements). Thus, the creepage distance 130 is not impacted or decreased by adding or providing the outer angled portion 118 and second conductor 120 to leadframe 110.

According to example embodiments, the outer conductive portion 114 may include a first conductor 116 provided at a first lateral position; a second conductor 120 provided at a second lateral position, the second conductor 120 being parallel to the first conductor 116; an outer angled portion 118 coupling the first conductor 116 to the second conductor 120; and where, based on an outer bending depth 142 provided by the outer angled portion 118, a second distance between the second conductor 120 and an upper surface of the DBM substrate 108 is less than a first distance between the first conductor 116 and the upper surface of the DBM substrate 108.

According to example embodiments, a maximum bond tool contact depth 155 within the semiconductor device package 100 during wire bonding is provided with respect to the second conductor 120 of the outer conductive portion 114 to one or more die or other components of the semiconductor device package 100; and where a creepage distance 130 is provided, or a creepage requirement is met, with respect to the first conductor 116 of the outer conductive portion 114.

According to example embodiments, based on an outer bending depth 142 provided by the outer angled portion 118, a second distance between the second conductor 120 and an upper surface of the DBM substrate 108 is less than a first distance between the first conductor 116 and the upper surface of the DBM substrate 108, where the second conductor 120 is configured to allow a bond tool 152 of a wirebond machine to reach a deeper bond tool contact depth 155 for wire bonding while one or more machine rails 140 of the wirebond machine contact or support the semiconductor device package 100 at the second conductor 120 as compared to the one or more machine rails 140 of the wirebond machine contacting or supporting the semiconductor device package 100 at the first conductor 116.

According to example embodiments, the second conductor 120 of the semiconductor device package 100 is configured to enable a bond tool 152 of a wirebond machine to reach a deeper bond tool contact depth 155 within the semiconductor device package 100 when one or more machine rails 140 of the wirebond machine contact or support the semiconductor device package 100 at the second conductor 120 instead of at the first conductor 116.

According to example embodiments, the outer angled portion 118 that connects the first conductor 116 and the second conductor 120 is configured to provide the second conductor 120 at a second lateral position that is closer to an upper surface of the DBM substrate 108 than the first conductor 116, to provide a machine rail height 129 (e.g., lower machine rail height, which is lower than machine rail height 128) with respect to the DBM substrate 108 to enable a deeper bond tool contact depth 155 (which is deeper than bond tool contact depth 135) within the semiconductor device package 100 during wire bonding.

According to example embodiments, the second conductor 120 of the outer conductive portion 114 is configured to enable one or more wirebond machine rails 140 of a wirebond machine to contact or support the semiconductor device package 100 at the second conductor 120 for a bond tool 152 to reach a deeper bond tool contact depth 155 within the semiconductor device package 100 during wire bonding as compared to the one or more machine rails 140 of the wirebond machine supporting or contacting the semiconductor device package at the first conductor 116.

According to example embodiments, a machine rail height 129 of a wirebond machine is provided at the second conductor 120 to enable a bond tool 152 of the wirebond machine to contact or touch deeper bond tool contact depth 155 within the semiconductor device package 100, as compared to a machine rail height 128 being provided at the first conductor 116.

According to example embodiments, the inner conductive portion 112 may include an inner angled portion 124 coupling a third conductor 122 provided at the first lateral position and a fourth conductor 126 that is coupled to the DBM substrate 108.

According to example embodiments, the third conductor 122 is coupled to and aligned with the first conductor 116; the third conductor 122 is provided at the first lateral position; and where the fourth conductor 126 is provided at a third lateral position that is closer to the DBM substrate 108 than the third conductor 122 at the first lateral position. For example, the fourth conductor 126 may be or may include a die attach pad (DAP) coupled (e.g., via soldering, sintering or welding) to the patterned metal layer 164 of the DBM substrate 108.

According to an example embodiment, with reference to FIG. 1, an apparatus may include a direct bonded metal (DBM) substrate 108 including at least a metal layer (e.g., patterned metal layer 164) coupled to an insulating layer 166; a leadframe 110 of a semiconductor device package 100 including an inner conductive portion 112 and an outer conductive portion 114, where the outer conductive portion 114 includes a first conductor 116 provided at a first lateral position, a second conductor 120 provided at a second lateral position that is disposed below the first lateral position, and an outer angled portion 118 coupling the first conductor 116 to the second conductor 120; where the inner conductive portion 112 includes an inner angled portion 124 and is coupled to the metal layer of the DBM substrate 108; where the inner conductive portion 112 is configured to be disposed in a molding material 136 of the semiconductor device package 100; where at least the second conductor 120 and the outer angled portion 118 of the outer conductive portion 114 are configured to be disposed outside of the molding material 136 of the semiconductor device package 100; and where at least the second conductor 120 and the outer angled portion 118 of the outer conductive portion 114 are configured to be cut or trimmed away from the semiconductor device package 100.

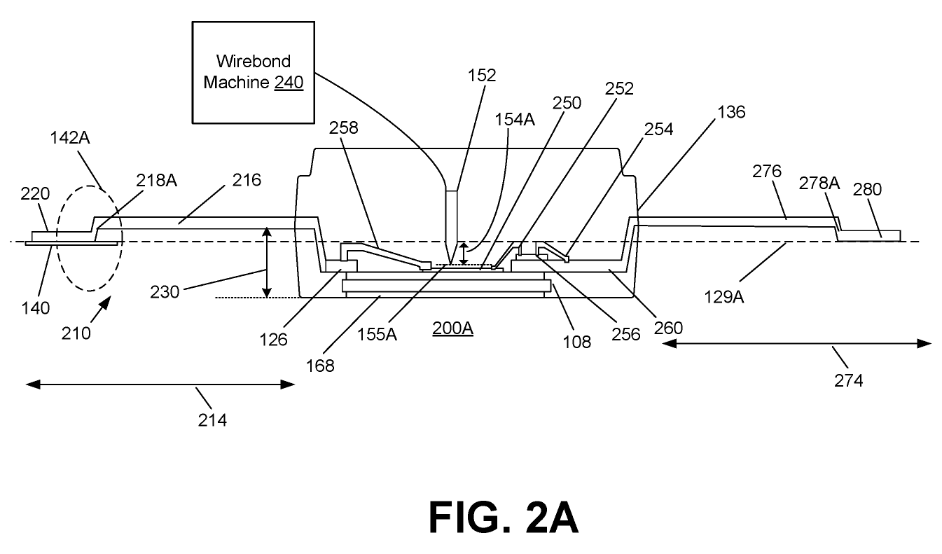

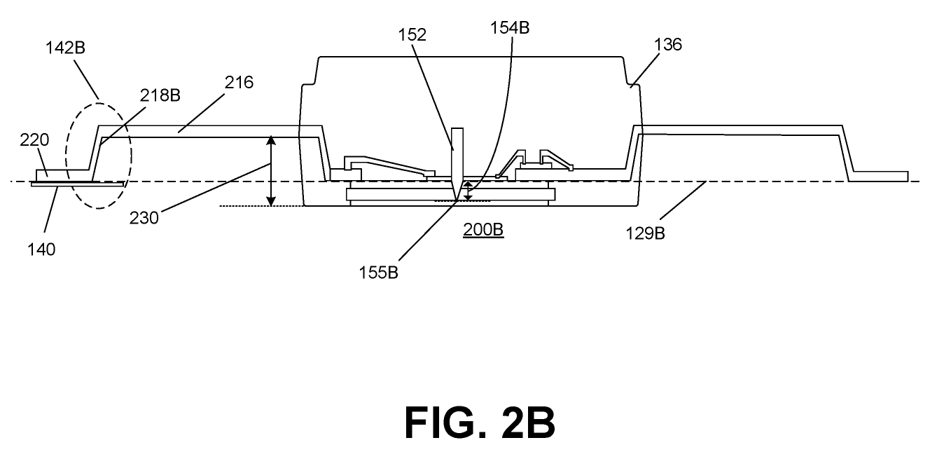

FIGS. 2A and 2B are cross-sectional views of semiconductor device packages in which an outer angled portion of a leadframe has different outer bending depths. The semiconductor device packages 200A and 200B shown in FIGS. 2A and 2B, respectively, are very similar to the semiconductor device package 100 shown in FIG. 1. A different or varying outer bending depth 142 (FIG. 1), such as either outer bending depth 142A (FIG. 2A) or outer bending depth 142B (FIG. 2B), may be controlled or adjusted as part of forming a leadframe 210, depending on how deep the bond tool 152 needs to contact or reach with semiconductor device package 200A and/or semiconductor device package 200B.

As shown in FIG. 2A, semiconductor device package 200A may include a leadframe 210 that includes an inner conductive portion (same or similar to that shown in FIG. 1) including a fourth conductor 126, an outer conductive portion 214 that includes a first conductor 216, a second conductor 220, and an outer angled portion 218A that includes an outer bending depth 142A. Leadframe 210 also may include outer conductive portion 274 that includes a conductor 276 (which may be at the same level or lateral position as first conductor 216), a conductor 280 (which may be at the same level as second conductor 220), and an outer angled portion 278A. Outer angled portion 278A may have a bending depth 142A (same bending depth 142A as outer angled portion 218A). Thus, machine rail height 129A may be provided based on different machine rails (e.g., front machine rail, and rear machine rail) contacting a lower surface of second conductor 220 and a lower surface of conductor 280, for example.

With reference to FIG. 2A, outer conductive portion 214 and outer conductive portion 274 are configured to be disposed outside of molding material 136. A portion of outer conductive portion 214, including at least outer angled portion 218A and second conductor 220, and a portion of outer conductive portion 274, including at least outer angled portion 278A and conductor 280, are configured to be cut or trimmed away from semiconductor device package 200A (e.g., after wirebonding has been performed). First conductor 216 and conductor 276 may form terminals of the semiconductor device package 200A. Although not shown in FIG. 2A, leadframe 210 may include many additional conductors in order to provide the various terminals of the semiconductor device package 200A, such as terminals provided by first conductor 216 and conductor 276. These terminals may remain after cutting or trimming away the outer conductors of the leadframe, such as first conductor 220 and conductor 280, and the outer angled portions, such as outer angled portion 218A and outer angled portion 278A, e.g., which may be provided and used to decrease machine rail height and thereby increase bond tool contact depth for wirebonding.

As shown in FIG. 2A, a creepage distance 230 is provided between the first conductor 216 and lower metal layer 168 of DBM substrate 108. Semiconductor device package 200A may include various components, e.g., including one or more semiconductor die, including die 250 and die 256, encapsulated within molding material 136. The semiconductor die may, for example, include a thermistor, a controller IC chip, a power device die (e.g., an IGBT die or a FRD die), or other die. A wirebond machine 240 may include a bond tool 152 for performing wire bonding for the semiconductor device package 200A, e.g., in which a bond wire 258 is connected by bond tool 152 between fourth conductor 126 and die 250, a bond wire 252 is connected between die 250 and die 256, and a bond wire 254 is connected between die 256 and conductor 260. These are merely examples of bond wires (also referred to as wire bonds), and other bond wires may be connected or attached to various components of the semiconductor device package 200A (FIG. 2A) and/or within the semiconductor device package 200B (FIG. 2B).

As shown in FIG. 2A, the machine rail 140 of wirebond machine 240 contacts or supports semiconductor device package 200A at a lower surface of second conductor 220 of the outer conductive portion 214, causing a height or level of the machine rail 140 to be provided or placed at machine rail height 129A during wire bonding. Based on the outer angled portion 218A having bending depth 142A and thus, placing machine rail 140 at machine rail height 129A, bond tool 152 has a bond tool contact range 154A down to bond tool contact depth 155A. Note that while outer bending depth 142A provides the second conductor 220 at a lower position than first conductor 216, creepage distance 130 for first conductor 216 (e.g., distance between first conductor 216 and lower metal layer 168) does not change or is not impacted by the use of outer angled portion 218A and second conductor 220 to lower machine rail 140 to the machine rail height 129A.

FIG. 2B illustrates a semiconductor device package 200B that is similar to the semiconductor device package 200A of FIG. 2A. However, the semiconductor device package 200B of FIG. 2B includes an outer angled portion 218B with an outer bending depth 142B that is greater than the outer bending depth 142A of outer angled portion 218A, which causes the height of the machine rail 140 to be placed or provided at machine rail height 129B (FIG. 2B), which is lower than machine rail height 129A (FIG. 2A). Based on the lower machine rail height 129B (e.g., which may result from the greater outer bending depth 142B of outer angled portion 218B), the bond tool 152 in FIG. 2B has a bond tool contact range 154B down to bond tool contact depth 155B, where bond tool contact depth 155B (FIG. 2B) is deeper or lower than bond tool contact depth 155A (FIG. 2A). The bond tool contact range 154A (FIG. 2A) may be the same as bond tool contact range 154B (FIG. 2B).

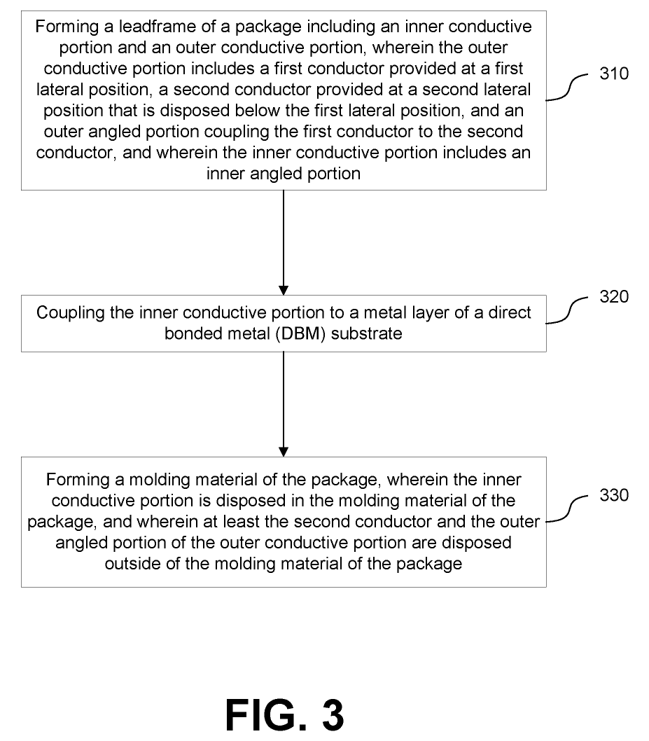

FIG. 3 is a flow chart illustrating a method of making a semiconductor device package. Operation 310 includes forming a leadframe of a package including an inner conductive portion and an outer conductive portion, where the outer conductive portion includes a first conductor provided at a first lateral position, a second conductor provided at a second lateral position that is disposed below the first lateral position, and an outer angled portion coupling the first conductor to the second conductor, and where the inner conductive portion includes an inner angled portion. Operation 320 includes coupling the inner conductive portion to a metal layer of a direct bonded metal (DBM) substrate. And, operation 330 includes forming a molding material of the package, where the inner conductive portion is disposed in the molding material of the package, and where at least the second conductor and the outer angled portion of the outer conductive portion are disposed outside of the molding material of the package.

According to example embodiments, with respect to the method of FIG. 3, the method may further include trimming away from the package at least the second conductor and the outer angled portion of the outer conductive portion.

According to example embodiments, with respect to the method of FIG. 3, a maximum bond tool contact depth within the package during wire bonding is provided with respect to the second conductor of the outer conductive portion to one or more die or other components of the package; and where a creepage requirement is met with respect to the first conductor of the outer conductive portion.

According to example embodiments, with respect to the method of FIG. 3, the method may further include performing wire bonding using a bond tool where a bond tool contact depth into the package is based on the second conductor making contact with a machine rail of a wirebond machine; and where a creepage distance is provided and/or a creepage requirement is met with respect to the first conductor of the outer conductive portion.

For example, with reference to FIG. 1, Outer conductive portion 114 of leadframe 110 may include a first conductor 116, a second conductor 120, and an outer angled portion 118 that couples the first conductor 116 with the second conductor 120. First conductor 116 may be provided at a first lateral (e.g., vertical) position, and second conductor 120 may be provided at a second lateral position that is disposed below the first lateral position. Thus, for example, the second conductor 120 may be laterally closer to DBM substrate 108 than first conductor 116. Outer angled portion 118 includes an outer bending depth 142, which is the lateral distance between first conductor 116 and second conductor 120.

As shown in FIG. 1, at least a portion of the outer conductive portion 114, including at least the outer angled portion 118 and the second conductor 120, may be configured to be cut or trimmed away from the semiconductor device package 100. Inner conductive portion 112 of leadframe 110 may include a third conductor 122, a fourth conductor 126, and an inner angled portion 124 that couples the third conductor 122 with the fourth conductor 126. Inner angled portion 124 includes an inner bending depth 144, which may be a lateral distance between third conductor 122 and fourth conductor 126, or may be the depth or distance that the inner angled portion 124 lowers (or decreases a position of) the fourth conductor 126 with respect to the third conductor 122. In example embodiments, the inner bending depth 144 may be greater than outer bending depth 142.

However, in example embodiments, with reference to FIG. 1, based on providing second conductor 120 that is disposed below first conductor 116, a deeper bond tool contact depth 155 (which is deeper within the semiconductor device package 100 than bond tool contact depth 135) may be achieved by lowering the machine rail height from machine rail height 128 to machine rail height 129, without decreasing the creepage distance 130 with respect to the first conductor 116. This deeper bond tool contact depth 155 may be achieved while maintaining the creepage distance 130 that meets the creepage requirement for the first conductor 116 and lower metal layer 168, since the lateral position of first conductor 116 is not moved or lowered (the creepage distance 130 is maintained). Also, a custom bond tool is not required. Rather, the outer bending depth 142 of outer angled portion 118 (FIG. 1) may be adjusted based on a design of the semiconductor device package 100 including a depth of various die or components, to allow a standard bond tool (e.g., having a fixed or maximum bond tool contact range) to be used for wire bonding for the semiconductor device package 100.

As shown in FIG. 1, based on the presence of second conductor 120 that is disposed below the first conductor 116, a machine rail 140 of the wirebond machine may make contact with or support a lower surface of second conductor 120, which causes the machine rail 140 to be provided at machine rail height 129. Machine rail height 129 (which may be based on the machine rail 140 contacting the second conductor 120) is lower than machine rail height 128 (which is based on machine rail 140 contacting the first conductor 116, in the absence of second conductor 120 and outer angled portion 118). The use of the second conductor 120 to provide a machine rail height 129, results in bond tool 152, with a bond tool contact range 154 (e.g, 1.1 mm), reaching a deeper bond tool contact depth 155. Bond tool contact depth 155 (based on use of second conductor 120 that is disposed below first conductor 116, making contact with the machine rail 140) may be deeper or further into semiconductor device package 100 than bond tool contact depth 135 (which is based on the first conductor 116 making contact with the machine rail 140, not shown in FIG. 1).

Also, with reference to FIGS. 2A – 2B, a different or varying outer bending depth 142 (FIG. 1), such as outer bending depth 142A (FIG. 2A) or outer bending depth 142B (FIG. 2B), may be controlled or performed as part of forming a leadframe 210, depending on how deep the bond tool 152 needs to contact or reach with semiconductor device package 200A and/or semiconductor device package 200B.

As shown in FIG. 2A, an outer angled portion 218A includes an outer bending depth 142A. A creepage distance 230 is provided between the first conductor 216 and lower metal layer 168 of DBM substrate 108. As shown in FIG. 2A, the machine rail 140 of wirebond machine 240 contacts or supports semiconductor device package 200A at a lower surface of second conductor 220 of the outer conductive portion 214, causing a height or level of the machine rail 140 to be provided or placed at machine rail height 129A during wire bonding. Based on the outer angled portion 218A having bending depth 142A and thus, placing machine rail 140 at machine rail height 129A, bond tool 152 has a bond tool contact range 154A down to bond tool contact depth 155A. With respect to FIG. 2B, the semiconductor device package 200B of FIG. 2B includes an outer angled portion 218B with an outer bending depth 142B that is greater than the outer bending depth 142A of outer angled portion 218A, which causes the height of the machine rail 140 to be placed or provided at machine rail height 129B (FIG. 2B), which is lower than machine rail height 129A (FIG. 2A). Based on the lower machine rail height 129B (e.g., which may result from the greater outer bending depth 142B of outer angled portion 218B), the bond tool 152 in FIG. 2B is able to reach a deeper bond tool contact depth 155B (FIG. 2B), which is deeper or lower than bond tool contact depth 155A (FIG. 2A).

Clause 1. An apparatus, comprising: a direct bonded metal (DBM) substrate including at least a metal layer coupled to an insulating layer; and a leadframe of a package including an inner conductive portion and an outer conductive portion, the outer conductive portion including an outer angled portion, wherein the inner conductive portion is configured to be disposed in a molding material of the package, wherein the inner conductive portion is coupled to the metal layer of the DBM substrate.

Clause 2. The apparatus of clause 1, wherein at least a portion of the outer conductive portion, including the outer angled portion, is configured to be disposed outside of the molding material of the package.

Clause 3. The apparatus of clause 1, wherein at least a portion of the outer conductive portion, including the outer angled portion, is configured to be trimmed or cut away from the package.

Clause 4. The apparatus of clause 1: wherein the inner conductive portion comprises a die attach pad (DAP) coupled to the metal layer of the DBM substrate; and wherein the apparatus further comprises a semiconductor die coupled to the DAP.

Clause 5. The apparatus of clause 1, wherein the outer conductive portion comprises: a first conductor provided at a first lateral position; a second conductor provided at a second lateral position that is disposed below the first lateral position, wherein the second lateral position of the second conductor is laterally closer to the DBM substrate than the first lateral position of the first conductor; and the outer angled portion couples the first conductor to the second conductor.

Clause 6. The apparatus of clause 1, wherein the outer conductive portion comprises: a first conductor provided at a first lateral position; a second conductor provided at a second lateral position, the second conductor being parallel to the first conductor, and the second conductor at the second lateral position being laterally closer to the DBM substrate than the first conductor; and the outer angled portion coupling the first conductor and the second conductor, the outer angled portion providing an outer bending depth of the outer conductive portion from the first conductor to the second conductor.

Clause 7. The apparatus of clause 5: wherein a creepage distance is provided, or a creepage requirement is met, with respect to the first conductor; and wherein a bond tool contact depth to one or more die or other components in the package during wire bonding is provided with respect to the second conductor.

Clause 8. The apparatus of clause 1, wherein the outer conductive portion comprises: a first conductor provided at a first lateral position; a second conductor provided at a second lateral position, the second conductor being parallel to the first conductor, and the second conductor at the second lateral position being laterally closer to the DBM substrate than the first conductor; and wherein a bond tool contact range from a machine rail of a wirebond machine to a component of the package is provided with respect to the second conductor based on contact of the machine rail of the wirebond machine with the second conductor.

Clause 9. The apparatus of clause 1, wherein the outer conductive portion comprises: a first conductor provided at a first lateral position; a second conductor provided at a second lateral position, the second conductor being parallel to the first conductor; an outer angled portion coupling the first conductor to the second conductor; and wherein, based on an outer bending depth provided by the outer angled portion, a second distance between the second conductor and an upper surface of the DBM substrate is less than a first distance between the first conductor and the upper surface of the DBM substrate.

Clause 10. The apparatus of clause 8: wherein a maximum bond tool contact depth within the package during wire bonding is provided with respect to the second conductor of the outer conductive portion to one or more die or other components of the package; and wherein a creepage distance is provided, or a creepage requirement is met, with respect to the first conductor of the outer conductive portion.

Clause 11. The apparatus of clause 8, wherein based on an outer bending depth provided by the outer angled portion, a second distance between the second conductor and an upper surface of the DBM substrate is less than a first distance between the first conductor and the upper surface of the DBM substrate, wherein the second conductor is configured to allow a bond tool of a wirebond machine to reach a deeper bond tool contact depth for wire bonding while one or more machine rails of the wirebond machine contact or support the package at the second conductor as compared to the one or more machine rails of the wirebond machine contacting or supporting the package at the first conductor.

Clause 12. The apparatus of clause 8, wherein the second conductor of the package is configured to enable a bond tool of a wirebond machine to reach a deeper bond tool contact depth within the package when one or more machine rails of the wirebond machine contact or support the package at the second conductor instead of at the first conductor.

Clause 13. The apparatus of clause 5, wherein the outer angled portion that connects the first conductor and the second conductor is configured to provide the second conductor at the second lateral position that is closer to an upper surface of the DBM substrate than the first conductor, to provide a lower wirebond machine rail height with respect to the DBM substrate to enable a deeper bond tool contact depth within the package during wire bonding.

Clause 14. The apparatus of clause 5, wherein the second conductor of the outer conductive portion is configured to enable one or more wirebond machine rails of a wirebond machine to contact or support the package at the second conductor for a bond tool to reach a deeper bond tool contact depth within the package during wire bonding as compared to the one or more machine rails of the wirebond machine supporting or contacting the package at the first conductor.

Clause 15. The apparatus of clause 5, wherein a machine rail height of a wirebond machine is provided at the second conductor to enable a bond tool of the wirebond machine to contact or touch deeper bond tool contact depth within the package, as compared to a machine rail height being provided at the first conductor.

Clause 16. The apparatus of clause 1 wherein the inner conductive portion comprises an inner angled portion coupling a third conductor provided at the first lateral position and a fourth conductor that is coupled to the DBM substrate.

Clause 17. The apparatus of clause 16: wherein the third conductor is coupled to and aligned with the first conductor; and wherein the third conductor is provided at the first lateral position; and wherein the fourth conductor is provided at a third lateral position that is closer to the DBM substrate than the third conductor at the first lateral position.

Clause 18. The apparatus of clause 16, wherein the fourth conductor comprises a die attach pad (DAP) coupled to the metal layer of the DBM substrate.

Clause 19. An apparatus comprising: a direct bonded metal (DBM) substrate including at least a metal layer coupled to an insulating layer; a leadframe of a package including an inner conductive portion and an outer conductive portion, wherein the outer conductive portion includes a first conductor provided at a first lateral position, a second conductor provided at a second lateral position that is disposed below the first lateral position, and an outer angled portion coupling the first conductor to the second conductor; wherein the inner conductive portion includes an inner angled portion and is coupled to the metal layer of the DBM substrate; wherein the inner conductive portion is configured to be disposed in a molding material of the package; wherein at least the second conductor and the outer angled portion of the outer conductive portion are configured to be disposed outside of the molding material of the package; and wherein at least the second conductor and the outer angled portion of the outer conductive portion are configured to be cut or trimmed away from the package.

Clause 20. The apparatus of clause 19, wherein a bond tool contact range within the package during wire bonding is provided with respect to the second conductor of the outer conductive portion to one or more die or other components of the package; and wherein a creepage distance is provided, or a creepage requirement is met, with respect to the first conductor of the outer conductive portion.

Clause 21. The apparatus of clause 19, wherein the second conductor of the package is configured to enable a bond tool of a wirebond machine to reach a deeper bond tool contact depth within the package when one or more machine rails of the wirebond machine contact or support the package at the second conductor instead of at the first conductor.

Clause 22. A method, comprising: forming a leadframe of a package including an inner conductive portion and an outer conductive portion, wherein the outer conductive portion includes a first conductor provided at a first lateral position, a second conductor provided at a second lateral position that is disposed below the first lateral position, and an outer angled portion coupling the first conductor to the second conductor, and wherein the inner conductive portion includes an inner angled portion; coupling the inner conductive portion to a metal layer of a direct bonded metal (DBM) substrate; and forming a molding material of the package, wherein the inner conductive portion is disposed in the molding material of the package, and wherein at least the second conductor and the outer angled portion of the outer conductive portion are disposed outside of the molding material of the package.

Clause 23. The method of clause 22, further comprising: trimming away from the package at least the second conductor and the outer angled portion of the outer conductive portion.

Clause 24. The method of clause 22: wherein a maximum bond tool contact depth within the package during wire bonding is provided with respect to the second conductor of the outer conductive portion to one or more die or other components of the package; and wherein a creepage requirement is met with respect to the first conductor of the outer conductive portion.

Clause 25. The method of clause 22, further comprising: performing wire bonding using a bond tool where a bond tool contact depth into the package is based on the second conductor making contact with a machine rail of a wirebond machine; and wherein a creepage requirement is met with respect to the first conductor of the outer conductive portion.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes. In some implementations, sintering can be, or can include a process of fusing particles together into one solid mass by using, for example, a combination of pressure and/or heat without melting the materials.

In some implementations, the DBM substrate can include an insulating layer disposed between a first metal layer and a second metal layer. The insulating layer can be, for example, a ceramic layer. In some implementations, the insulating layer can be or can include, for example, a ceramic material such as alumina (Al2O3) or aluminum nitride (AlN)).

In some implementations, the first metal layer and/or the second metal layer can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate. In some implementations, such as in DBC substrate implementations, the first metal layer and/or the second metal layer is a copper layer.

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor dies may be also connected to lead frame posts by electrical connections such as wirebonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

In some implementations, a mold material (e.g., molding material or compound, an encapsulation material) can be or can include a non-conducting layer/material.

One or more wire bonds (or bond wires), which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer)

In some implementations, a module (e.g., a package including a semiconductor device) can be included in another module. The module can be referred to as a package. For example, one or more modules can be one or more sub modules included within another module. In other words, a first module can be included as a sub module within a second module.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An apparatus, comprising:
a direct bonded metal (DBM) substrate including at least a metal layer coupled to an insulating layer; and
a leadframe of a package including an inner conductive portion and an outer conductive portion, the outer conductive portion including an outer angled portion, wherein the inner conductive portion is configured to be disposed in a molding material of the package, wherein the inner conductive portion is coupled to the metal layer of the DBM substrate.

2. The apparatus of claim 1, wherein at least a portion of the outer conductive portion, including the outer angled portion, is configured to be disposed outside of the molding material of the package.

3. The apparatus of claim 1, wherein at least a portion of the outer conductive portion, including the outer angled portion, is configured to be trimmed or cut away from the package.

4. The apparatus of claim 1:
wherein the inner conductive portion comprises a die attach pad (DAP) coupled to the metal layer of the DBM substrate; and
wherein the apparatus further comprises a semiconductor die coupled to the DAP.

5. The apparatus of claim 1, wherein the outer conductive portion comprises:
a first conductor provided at a first lateral position;
a second conductor provided at a second lateral position that is disposed below the first lateral position, wherein the second lateral position of the second conductor is laterally closer to the DBM substrate than the first lateral position of the first conductor; and
the outer angled portion couples the first conductor to the second conductor.

6. The apparatus of claim 1, wherein the outer conductive portion comprises:
a first conductor provided at a first lateral position;
a second conductor provided at a second lateral position, the second conductor being parallel to the first conductor, and the second conductor at the second lateral position being laterally closer to the DBM substrate than the first conductor; and
the outer angled portion coupling the first conductor and the second conductor, the outer angled portion providing an outer bending depth of the outer conductive portion from the first conductor to the second conductor.

7. The apparatus of claim 5:
wherein a creepage distance is provided, or a creepage requirement is met, with respect to the first conductor; and
wherein a bond tool contact depth to one or more die or other components in the package during wire bonding is provided with respect to the second conductor.

8. The apparatus of claim 1, wherein the outer conductive portion comprises:
a first conductor provided at a first lateral position; and
a second conductor provided at a second lateral position, the second conductor being parallel to the first conductor, and the second conductor at the second lateral position being laterally closer to the DBM substrate than the first conductor; and
wherein a bond tool contact range from a machine rail of a wirebond machine to a component of the package is provided with respect to the second conductor based on contact of the machine rail of the wirebond machine with the second conductor.

9. The apparatus of claim 1, wherein the outer conductive portion comprises:
a first conductor provided at a first lateral position;
a second conductor provided at a second lateral position, the second conductor being parallel to the first conductor; and
an outer angled portion coupling the first conductor to the second conductor; and
wherein, based on an outer bending depth provided by the outer angled portion, a second distance between the second conductor and an upper surface of the DBM substrate is less than a first distance between the first conductor and the upper surface of the DBM substrate.

10. The apparatus of claim 8, wherein a maximum bond tool contact depth within the package during wire bonding is provided with respect to the second conductor of the outer conductive portion to one or more die or other components of the package; and
wherein a creepage distance is provided, or a creepage requirement is met, with respect to the first conductor of the outer conductive portion.

11. The apparatus of claim 8, wherein based on an outer bending depth provided by the outer angled portion, a second distance between the second conductor and an upper surface of the DBM substrate is less than a first distance between the first conductor and the upper surface of the DBM substrate; and
wherein the second conductor is configured to allow a bond tool of a wirebond machine to reach a deeper bond tool contact depth for wire bonding while one or more machine rails of the wirebond machine contact or support the package at the second conductor as compared to the one or more machine rails of the wirebond machine contacting or supporting the package at the first conductor.

12. The apparatus of claim 8, wherein the second conductor of the package is configured to enable a bond tool of a wirebond machine to reach a deeper bond tool contact depth within the package when one or more machine rails of the wirebond machine contact or support the package at the second conductor instead of at the first conductor.

13. The apparatus of claim 5, wherein the outer angled portion that connects the first conductor and the second conductor is configured to provide the second conductor at the second lateral position that is closer to an upper surface of the DBM substrate than the first conductor, to provide a lower wirebond machine rail height with respect to the DBM substrate to enable a deeper bond tool contact depth within the package during wire bonding.

14. The apparatus of claim 5, wherein the second conductor of the outer conductive portion is configured to enable one or more machine rails of a wirebond machine to contact or support the package at the second conductor for a bond tool to reach a deeper bond tool contact depth within the package during wire bonding as compared to the one or more machine rails of the wirebond machine supporting or contacting the package at the first conductor.

15. The apparatus of claim 5, wherein a machine rail height of a wirebond machine is provided at the second conductor to enable a bond tool of the wirebond machine to contact or touch deeper bond tool contact depth within the package, as compared to a machine rail height being provided at the first conductor.

16. The apparatus of claim 1 wherein the inner conductive portion comprises an inner angled portion coupling a third conductor provided at a first lateral position and a fourth conductor that is coupled to the DBM substrate.

17. The apparatus of claim 16, wherein the third conductor is coupled to and aligned with the first conductor;
wherein the third conductor is provided at the first lateral position; and
wherein the fourth conductor is provided at a third lateral position that is closer to the DBM substrate than the third conductor at the first lateral position.

18. The apparatus of claim 16, wherein the fourth conductor comprises a die attach pad (DAP) coupled to the metal layer of the DBM substrate.

19. An apparatus comprising:
a direct bonded metal (DBM) substrate including at least a metal layer coupled to an insulating layer; and
a leadframe of a package including an inner conductive portion and an outer conductive portion, wherein the outer conductive portion includes a first conductor provided at a first lateral position, a second conductor provided at a second lateral position that is disposed below the first lateral position, and an outer angled portion coupling the first conductor to the second conductor;
wherein the inner conductive portion includes an inner angled portion and is coupled to the metal layer of the DBM substrate;
wherein the inner conductive portion is configured to be disposed in a molding material of the package;
wherein at least the second conductor and the outer angled portion of the outer conductive portion are configured to be disposed outside of the molding material of the package; and
wherein at least the second conductor and the outer angled portion of the outer conductive portion are configured to be cut or trimmed away from the package.

20. The apparatus of claim 19, wherein a bond tool contact range within the package during wire bonding is provided with respect to the second conductor of the outer conductive portion to one or more die or other components of the package; and
wherein a creepage distance is provided, or a creepage requirement is met, with respect to the first conductor of the outer conductive portion.

21. The apparatus of claim 19, wherein the second conductor of the package is configured to enable a bond tool of a wirebond machine to reach a deeper bond tool contact depth within the package when one or more machine rails of the wirebond machine contact or support the package at the second conductor instead of at the first conductor.

22. A method, comprising:
forming a leadframe of a package including an inner conductive portion and an outer conductive portion, wherein the outer conductive portion includes a first conductor provided at a first lateral position, a second conductor provided at a second lateral position that is disposed below the first lateral position, and an outer angled portion coupling the first conductor to the second conductor, and wherein the inner conductive portion includes an inner angled portion;
coupling the inner conductive portion to a metal layer of a direct bonded metal (DBM) substrate; and
forming a molding material of the package, wherein the inner conductive portion is disposed in the molding material of the package, and wherein at least the second conductor and the outer angled portion of the outer conductive portion are disposed outside of the molding material of the package.

23. The method of claim 22, further comprising:
trimming away from the package at least the second conductor and the outer angled portion of the outer conductive portion.

24. The method of claim 22, wherein a maximum bond tool contact depth within the package during wire bonding is provided with respect to the second conductor of the outer conductive portion to one or more die or other components of the package; and
wherein a creepage requirement is met with respect to the first conductor of the outer conductive portion.

25. The method of claim 22, further comprising:
performing wire bonding using a bond tool where a bond tool contact depth into the package is based on the second conductor making contact with a machine rail of a wirebond machine; and
wherein a creepage requirement is met with respect to the first conductor of the outer conductive portion.
